(19) United States
(12) Patent Application Publication
(10) Pub. No.: US 2004/0001371 A1
(43) Pub. Date: Jan. 1, 2004

(54) Information storage and retrieval device using macromolecules as storage media

(75) Inventors: Masud Mansuripur, Tucson, AZ (US); Pramod Kumar Khulbe, Tucson, AZ (US); Joseph Walter Perry, Tucson, AZ (US); Stephen Michael Kuebler, Tucson, AZ (US); James Kevin Erwin, Tucson, AZ (US)

Correspondence Address: Norman P. Soloway, HAYES SOLOWAY P.C., 130 W. Cushing Street, Tucson, AZ, 85701, US

(73) Assignee: The Arizona Board of Regents on Behalf of the University of Arizona

(21) Appl. No.: 10/600,935

(22) Filed: Jun. 20, 2003

Related U.S. Application Data
(60) Provisional application No. 60/391,639, filed on Jun. 26, 2002.

(51) Int. Cl. G11C 7/00

(52) U.S. Cl. 365/200

(57) ABSTRACT

A storage device for the storage and retrieval of arbitrary sequences of binary information provides areal densities exceeding terabytes per square centimeter (TB/cm²) and even petabytes per square centimeter (PB/cm²) in a 3D configuration. The information is encoded in long strands of biological or non-biological molecules such as artificial DNA, RNA or other synthetic molecules that form a macromolecule. The strands are written in-situ and, in some cases synthesized in-situ, transported to and from read and write stations and memory locations on the device. The data is read out by detecting individual bases or collection of bases directly from the strand.

### CROSS-REFERENCE TO RELATED APPLICATIONS

This application claims benefit of priority under 35 U.S.C. 120 to U.S. provisional application Serial No. 60/391,639 entitled “Information Storage and Retrieval using Macro-molecules as Storage Media” filed on Jun. 26, 2002, the entire contents of which are incorporated by reference.

### GOVERNMENT LICENSE RIGHTS

The U.S. Government has a paid-up license in this invention and the right in limited circumstances to require the patent owner to license others on reasonable terms as provided for by the terms of Grant No. DMR-0120967 awarded by the National Science Foundation.

### BACKGROUND OF THE INVENTION

1. Field of the Invention

This invention relates to information storage and retrieval and more-specifically to an information storage and retrieval device using macromolecules as the storage media.

2. Description of the Related Art

Presently, secondary data storage is the domain of hard disks, removable magnetic media (e.g., zip disk, magnetic tape), optical media (e.g., CD-R, DVD-RW), and magneto-optical media. These storage devices are inherently two-dimensional in the sense that information is recorded on a thin layer at the surface of a disk or tape, although many disks can certainly be stacked to increase their volumetric capacity. The highest recording density in hard disk products today stands at 8 gigabits/cm², while laboratory demonstrations have achieved 20 gigabits/cm². Recording density is dictated by the gap dimensions that can be manufactured in the inductive head, stability of magnetic domains in thin magnetic films, and the signal-to-noise ratio obtained from magneto-resistive readout heads. In the case of optical disks, the wavelength of the laser light used for recording and readout as well as the media noise is the fundamental barrier to achieving higher storage densities.

Considering the potential of conventional storage media and possible advances in read/write heads and media technology, the current methods can conceivably be improved to yield tens of gigabits/cm² recording densities and several gigabits/sec data transfer rates. Optimistic prospects are to achieve perhaps 75-150 gigabits/cm² with perpendicular recording and maybe a factor of 5-10 more with heat-assisted magnetic recording. However, going beyond these milestones seems to be impossible owing to fundamental physical limitations.

Magnetic disk drives on the market today have capacities of ˜100 GB and data rates of ˜500 Mb/s. Optical drives are exemplified by DVD-RW drives: each 12 cm-diameter DVD platter has a capacity of 4.7 GB and a 1× data rate of 11.06 Mb/s. The next generation DVD's are expected to use blue lasers (λ˜400 nm) and have a capacity of ˜25 GB per platter. Double layer disks with capacities of ˜50 GB are also being planned. The tentative date of introduction of the blue DVD is sometime in 2005. Beyond this, the next-generation optical drives planned for the year 2010 and beyond are expected to have capacities in excess of 100 GB and data rates approaching 1 Gb/s, although several technical hurdles must be overcome before such devices can even be demonstrated in the laboratory. It is also not clear whether phase-change or magneto-optical media will be the most suitable for this fourth generation of optical disk drives.

Several proposals have been made for using polymers for electronic based molecular memories. For example, Hopfield, J. J., Onuchic, J. N. and Beratan, D. N., “A Molecular Shift Register”, Science, 241, p. 817, 1988, discloses a polymer based shift register memory which incorporates charge transfer groups. Others have proposed an electronic based DNA memory (see Robinson et al, “The Design of a Biochip: A Self-Assembling Molecular-Scale Memory Device”, Protein Engineering, 1:295-300 (1987)). In this case, DNA is used with electron conducting polymers for a molecular memory device. Both concepts for these molecular electronic memories do not provide a viable mechanism for inputting data (write) and for outputting data (read).

U.S. Pat. Nos., 5,834,404, 6,385,080, and 6,067,246 assigned to Nanogen, Inc. disclose an optical memory system including memory cells and utilizing synthetic DNA as the media for information storage. The mechanisms for writing, reading, and storage of information are similar to conventional optical disk data storage in that the storage device contains specific fixed locations in which the information is stored. The storage device is then rotated around a central axis under focused light beams so that the read and/or write laser beams can access various locations on the storage device. What distinguishes Nanogen's technique from conventional optical recording techniques is that synthetic DNA is used as a support structure to contain more than one bit of information. By modifying the wavelength, polarization state, or the intensity of the incident radiation, it is possible to modify the properties of the additional acceptor, donor, and quencher molecules that are attached to the DNA and store multiple bits of information in each and every cell. The binary data is thus encoded in the relationship between the acceptor and donor molecules and not in the base sequence of the DNA itself. The encoded data is then read out optically using conventional photodetection techniques commonly used with existing optical storage media.

In summary, both magnetic and optical technologies that dominate today's storage market-place may have the potential to address the needs of a market that demands terabyte capacity in small form factor in the near future, but it is highly doubtful that these same technologies can reach into the petabyte domain. Nanogen's technology has the potential to increase the capacity of present-day optical media by one to two orders of magnitude, but it is ultimately hampered by the same limitations as confronted by conventional optical recording media, namely, the diffraction-limited size of the focused spot, lack of sufficient signal-to-noise ratio, complexity of read/write operations, lack of erasability, and so on. The fundamental limitations on the currently existing paradigms cannot be overcome by evolutionary enhancements in those systems. This invention constitutes a revolutionary new approach.

### SUMMARY OF THE INVENTION

The present invention provides a device and method for the storage and retrieval of arbitrary sequences of binary information at areal densities exceeding terabytes per square centimeter (TB/cm²) in 2D devices and even petabytes per square centimeter (PB/cm²) in 3D configurations.

This is accomplished by storing the information in long strands of biological or non-biological molecules such as artificial DNA, RNA or other synthetic molecules known as “macromolecules”. The molecules must be capable of being strung together to form a long stable chain in which the molecular bases either have multiple stable states, e.g. (0,1), or represent distinguishable-base units,.e.g. {(0),(1)} or {(00,01,10,11)}. For example, certain polymers consist solely of identical bases but these bases can be selectively transformed into distinct excited states under the influence of external forces. DNA consists of four bases adenine (A), thymine (T), cytosine (C) and guanine (G), which can be used to represent 2-bit sequences in a quaternary system.

Binary sequences of data are “written” in-situ into these molecular strands. In some cases, such as with DNA and RNA individual bases are synthesized into a strand in-situ to encode the date. In others, blank strands are provided and modified in-situ to encode the date. In most cases, the data is encoded into the base-sequence of the strand itself. However, in at least one embodiment, the strand is used as a support structure on which to write the data.

Once written, the strands are transported on the device and stored at a particular memory address. Transportation may be accomplished using electric field gradients, micro-fluidic pumps or optical tweezers.

A strand is “read out” by moving it from its memory address to a read location where a read head detects each base or collection of bases to read out the encoded binary data directly from the strand. This can be achieved by measuring fluctuations in ionic current through a nano-pore or with a microscopic probe that measures, for example, a tunneling current or a deflection. Any unwanted molecules may be destroyed (“erased”) or modified to represent new data blocks (“overwrite”).

A typical storage device would include a number of “parking lots” for storing the molecular strands in liquid-filled canals and a like number of “actuated gates” that control the strands' entrance to and exit from the respective parking lots. These gates have unique addresses and are controlled by an external signal via addressing lines. A “race track” is connected to the parking lots via the actuated gates and acts as a highway for transporting molecular strands along liquid filled canals. A “transport mechanism” moves the molecular strands to and from the parking lots via the racetrack. A “write station” includes one or more actuated gates (“inlets”) for receiving raw molecular material (bases or strands), a write head that writes a particular binary sequence into a strand, and an actuated gate (“outlet”) connected to the racetrack. A “read station” includes an actuated gate (“inlet”) for receiving a strand from the racetrack, a read head for reading out the binary sequence from the strand, and one or more actuated gates (“outlets”) for destroying or reprocessing the strands.

To read/write a strand in this device from or to a particular parking lot (memory address), the actuation gates, e.g. micro-fluidic valves, are controlled such that the addressed parking lot's canal is connected to form a closed-loop with the racetrack and read/write stations. The transport mechanism, e.g. micro-fluidic pumps, electric-field gradient or optical tweezers, causes the strand to flow in the liquid filled canals between the parking lot and read/write station.

The storage device is fabricated using a number of different technologies. Patterning technologies such as photolithography, e-beam lithography, two-photon fabrication and laser micromachining are used to form the ridges and canals in the substrate that form the parking lots and race tracks and 3D microstructures on the substrate that form the chambers for the read and write stations. Nano-fabrication technologies may be used to form a nano-pore in the read chambers. Micro-fluidic device fabrication is used to form micro-values for the actuation gates and, in one embodiment, micro-pumps for the transfer mechanism. CMOS processing is used to form a control wafer that is mounted on top of the substrate and provides external control for the micro-valves, micro-pumps, etc. Lastly, chemical synthesis technologies are used to synthesize the molecules into the strands on the device.

These and other features and advantages of the invention will be apparent to those skilled in the art from the following detailed description of preferred embodiments, taken together with the accompanying drawings, in which:

### BRIEF DESCRIPTION OF THE DRAWINGS

FIG. 1 is a functional block diagram of a macromolecule-based storage device in accordance with the present invention;

FIGS. 2a through 2d are diagrams of DNA and RNA material having distinctive base units,and a monomer material having multiple-stable and unique states;

FIG. 3 illustrates the steps of writing, storing, reading and disposing of the macromolecule strand;

FIGS. 4a and 4b are schematic diagrams of the storage device shown in FIG. 1;

FIGS. 5a and 5b are diagrams showing a two-state micro-valve as an actuated gate;

FIGS. 6a through 6c are electric field, micro-fluidic pump and optical tweezers embodiments of the transport mechanism;

FIGS. 7a through 7e are embodiments of a write station;

FIGS. 8a through 8c illustrate a technique for reading out the strand using a nano-pore and ionic current;

FIGS. 9a through 9c illustrate a solid-state nano-pore for use in the read station and a method of fabrication;

FIG. 10 illustrates another technique for reading out the strand using a microscopic probe;

FIG. 11 is an illustration of a multi-layer storage device; and

FIG. 12 is an illustration of parallel read/write capability in a storage device.

### DETAILED DESCRIPTION OF THE INVENTION

The present invention provides a storage media and device for the storage and retrieval of arbitrary sequences of binary information at areal densities exceeding terabytes per square centimeter (TB/cm²) and even petabytes per square centimeter (PB/cm²) by storing the information in long strands of biological or non-biological molecules such as artificial DNA, RNA or other synthetic molecules known as “macromolecules”. A macromolecule is a long strand of molecules, which are made up of a sequence of bases. The strands are written in-situ, transported to and from read and write stations and memory locations on-device, and read-out by detecting individual bases or collections of bases in the strand thus avoiding the limitations associated with conventional storage devices. In most cases, the binary data is encoded into the base-sequence of the strand itself. Furthermore, when the media contains distinct bases such as DNA or RNA, the strand is synthesized in-situ to encode the binary data.

Storage Device and Media

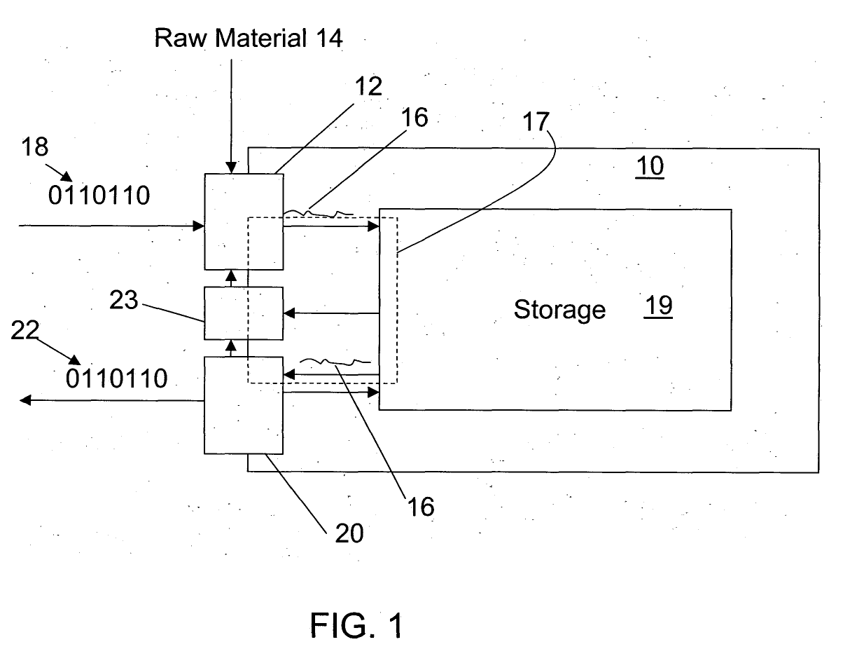

As shown in FIG. 1, a storage device 10 includes a write head 12 that receives raw molecular material 14 and writes the sequence of binary data 18 in-situ into strands 16. In some cases as exemplified by Write Mechanisms 1, 2 and 5 below, the media is provided as distinct molecular bases and the write head synthesizes the bases to form strand 16 and thereby encode the data. In other cases, as exemplified by Write Mechanisms 3 and 4 below, the raw media is provided as blank strands 16 and the write head modifies the strands to encode the data. In most cases, Write Mechanism 1, 2, 3 and 5 below, the data is encoded in the base-sequence of the strand itself. In at least one embodiment, Write Mechanism 4 below, the strand serves as a support structure on which the data is written.

A transport mechanism 17 transports the strands to a storage block 19. As exemplified in Transport Mechanisms 1, 2 and 3 below, the transport mechanism may be an electric field gradient, micro-fluidic pumps or optical tweezers. Other mechanisms may also be developed for moving strands around the device without departing from the scope of the invention.

In response to a read command, transport mechanism 17 moves a strand out of the storage block and to a read head 20 that detects individual bases or collections of bases (depending on the precision of the read head) in the strand to read out a sequence of binary data 22. The read head may embody a nano-pore and detect fluctuations in ionic current (Read Mechanism 1), may use a microscopic probe to measure tunneling current or atomic force deflections (Read Mechanism 2) or other suitable mechanisms.

Once read, the strand is directed to a recycle/dump unit 23 that disposes of the strand by either destroying it or recycling the material for reuse by the write head or directed back to the storage block. In some cases, the strand may be moved directly from the storage block to the recycle/dump unit. The read and write heads are typically integrated on-device to enhance access times, throughput and data rate.

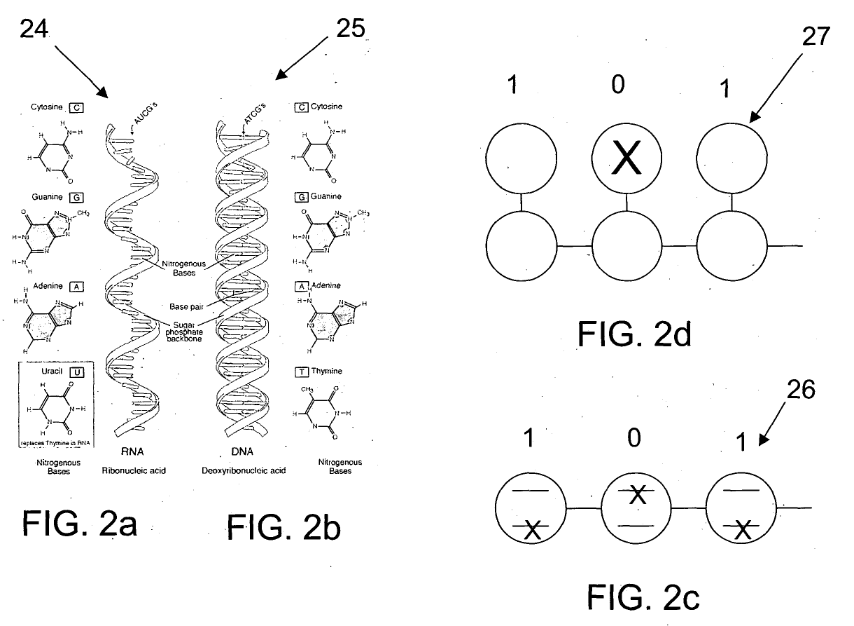

A wide range of molecular materials can be used as the storage media. Specifically,, any group of distinct molecules that can be strung together to form a long macro-molecular chain of stable and distinguishable bases could, in principle, be a candidate data storage medium. As shown in FIGS. 2a and 2b, RNA and DNA molecules 24 and 25, respectively, with their four distinct bases adenine (A), uracil (U), cytosine (C) and, guanine (G) for RNA and adenine (A), thymine (T), cytosine (C) and guanine (G) for DNA, constitute two examples of the proposed storage media. Since any base can be attached to any other base, these biological molecules provide the foundation for a quaternary data storage system, where each base would represent two bits of information “00”, “01”, “10” and “11” in a base sequence. Alternately, a device could use only two of the base units and assign them “0” and “1”. The double helix of DNA has a period of 3.4 nm (one helical turn), corresponding to about 10 base pairs or 20 bits per period. Therefore, the linear density of storage along the DNA (or RNA) molecule is 1 bit per 0.17 nm, or 149 Mbits/inch, which is orders of magnitude better than the available electronic, magnetic, and optical technologies. Biological protein molecules with their twenty amino-acid constituents as well as synthetic proteins provide another class of potential data storage media.

Molecules that do not have distinctive bases may also be used. Any molecule having a base that can be placed in two or more physically and/or chemically distinct, stable states and can, in addition, be strung into a long macro-molecular chain, is a candidate for the storage media. In this case, the strand is synthesized, most likely off-device, and then provided to the write station, which encodes the strand with the binary data. As shown in FIG. 2c, a molecule 26 that can be stably switched between a ground state and an excited state is a candidate. As shown in FIG. 2d, a molecule 27 that can be physically altered via a localized probe such as a scanning tunneling microscope tip or atomic force microscope tip or similar device to have two different states is also a candidate.

There are numerous other long-chain molecules (natural or synthetic) that can be fabricated by attaching together molecules from a group of two or more distinct bases in any arbitrary sequence. There are other long-chain molecules that consist solely of identical bases (monomers), but these bases can be selectively transformed into distinct “excited” states under the influence of external forces (e.g., electrical, optical, magnetic, thermal, chemical, mechanical, etc.). As long as these chains of distinguishable bases are stable within the environment of the storage device in which they are stored and manipulated, they are potential candidates for the proposed storage scheme.

The binary data sequences and their corresponding strands can be represented or coded in a variety of ways to improve stability of the recorded information. The simplest but potentially least stable approach is to encode the binary data into a single strand similar to the RNA shown in FIG. 2a. The stability of stored information can be improved by using double-helix strands as shown in FIG. 2b for DNA. Various thermal mechanisms (e.g., localized electrical or optical heating using an electrode or a focused laser beam) may be used to raise the temperature of the device locally, in order to cause the separation of the double-stranded DNA molecule into two single strands, before reading the (negatively-charged) single strand. Multiple copies of the same DNA sequence can be stored to increase the reliability of storage, as well as to increase the signal-to-noise ratio during readout. Taking advantage of the latter feature assumes, of course, that multiple copies of a given DNA loop can be aligned and moved synchronously through the system. This may be possible if complementary base sequences are introduced at fixed intervals along each DNA molecule to allow the molecules to stick together at the location of these short, complementary blocks. (C is always complementary to G and A to T; thus, for example, a short segment such as ACTTGA is complementary to TGAACT.)

As mentioned earlier, to ensure the stability of the recorded information, it is desirable to store DNA-encoded data in the Watson-Crick double-helix form (B-DNA), with each base hybridized to its complementary base pair. In one scheme, a single DNA strand could be transported to a hybridization station, where the pH and electrolyte conditions are adjusted to promote enzyme-mediated chemistries that build the complement to the DNA strand and then hybridize to form the B-DNA sequence. A potentially more rapid way of creating the stabilized data strands is to write the DNA data strand in palindromic form. DNA palindromes are contiguous inverted repeats of a base sequence within the strand. An example of a DNA palindromic sequence would be AATCGTATACGATT, for which the underlined sequence is an inverted repeat of the non-underlined sequence. Under typical conditions, palindromic sequences rapidly fold back upon themselves and hybridize forming a loop or “hairpin”-DNA structure. As nearly each base of the structure is hydrogen-bonded to its complement, hairpin structures are stabilized just like B-DNA. Because palindromic sequence hybridization is a zero-order kinetic process, it. occurs much more rapidly than hybridization of “random-sequence” DNA. Data stored in a palindromic form would require twice the write time, but also provides an internal check, as the data sequence is repeated within the strand.

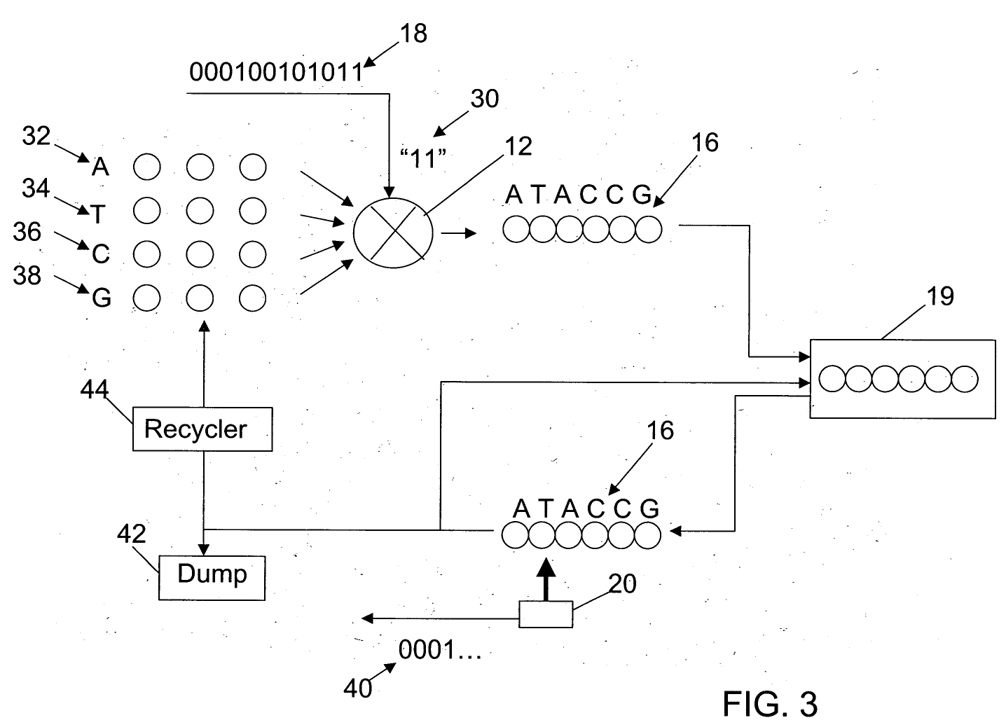

A typical write-store-read cycle for the storage device is illustrated in FIG. 3. In this particular scheme, write head 12 reads successive two-bit chunks 30 of the binary data sequence 18 to be stored and retrieves the appropriate DNA base from reservoirs 32, 34, 36 and 38 of A, T, C and G nucleic-acid bases. The write head attaches the base to strand 16 in-situ and repeats the process until the strand represents the input data sequence. The write head may create single or double-helix strands and/or may incorporate other coding techniques to improve the stability of the stored data. The strand is then transported to storage block 19 where it is stored. In response to a read command, the strand is moved out of the storage block and transported to read head 20 that detects the occurrence of the different bases, either individually or in collections, and outputs the corresponding binary sequence 40. The strand is then directed to either a dump 42 where the material is destroyed and removed from the device, a recycler 44 where the bases are separated and recycled or back to storage block 19.

In one configuration, the reservoirs are, located “off-device” and the strands, when no longer needed, are expelled from the device and destroyed. In another configuration, the reservoirs are located “on-device” and the strands, when no longer needed, are broken apart into their constituent molecules and the molecules directed to their respective reservoirs. Hybrid configurations would include on-device reservoirs that are periodically replenished from external reservoirs so that some media is recycled and some destroyed.

Single-Layer Storage Device

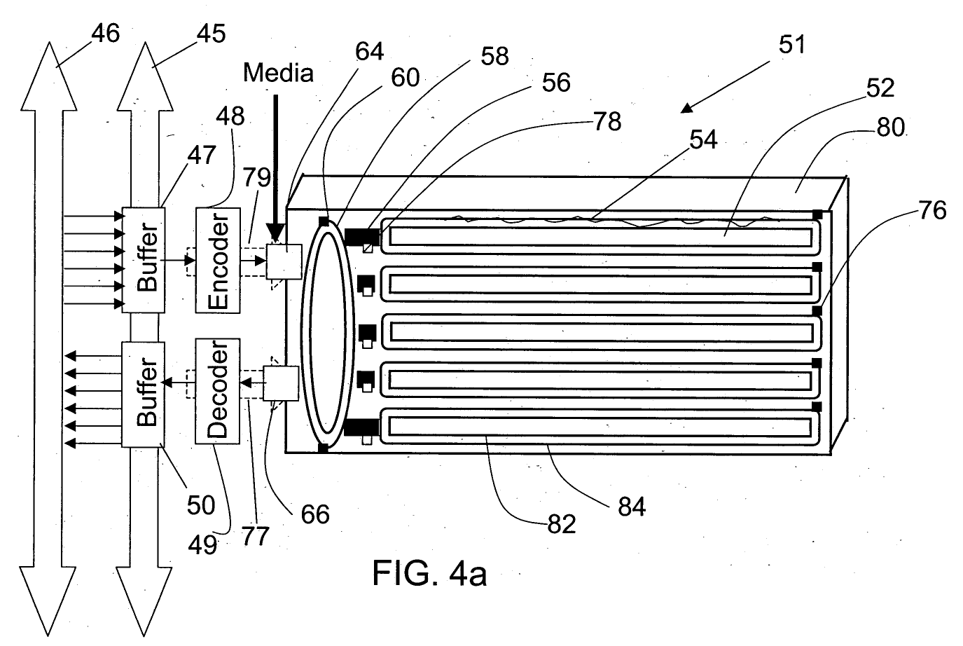

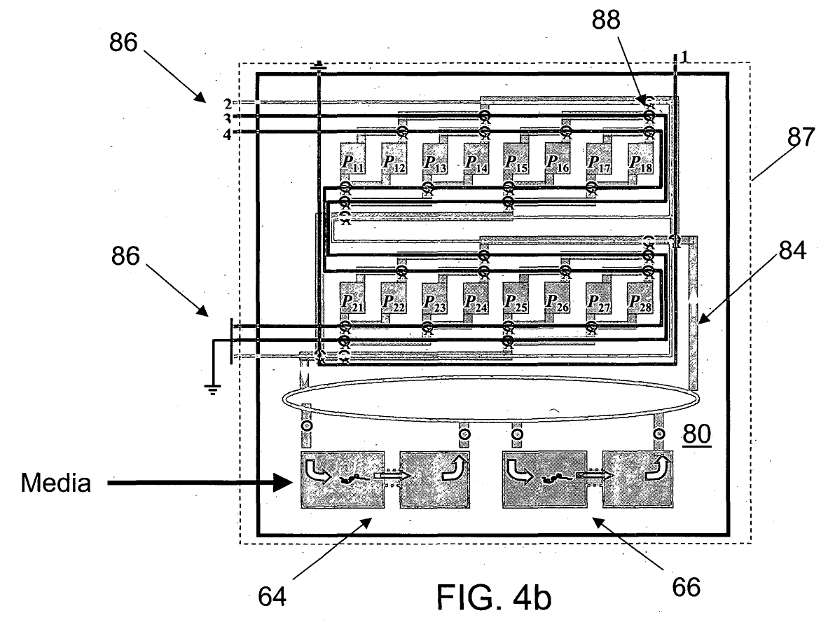

An embodiment of a single-layer storage device 50 is shown in FIGS. 4a and 4b. The storage scheme is in many ways reminiscent of the techniques used in the 1970's in magnetic bubble devices. Address and data buses 45 and 46, respectively, communicate address and data information as strings of binary data to and from a storage device 51. Address and data information is loaded into a buffer 47 and passed through an encoder 48 that adds redundancy for error correction and/or intelligently encodes the data to make the data compatible with allowed molecular sequences and communicates with write station 64. Data read out of the device from read station 66 is passed through decoder 49, loaded into buffer 50 and transferred to data bus 46.

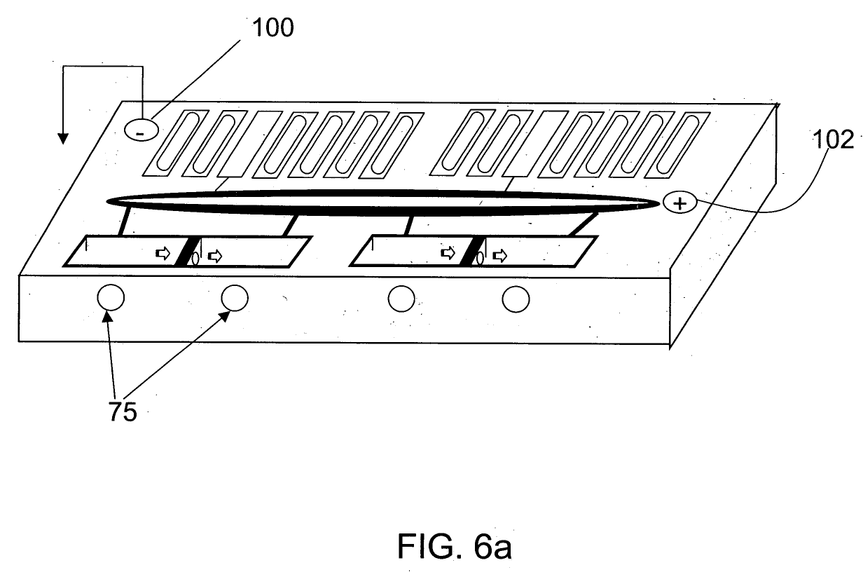

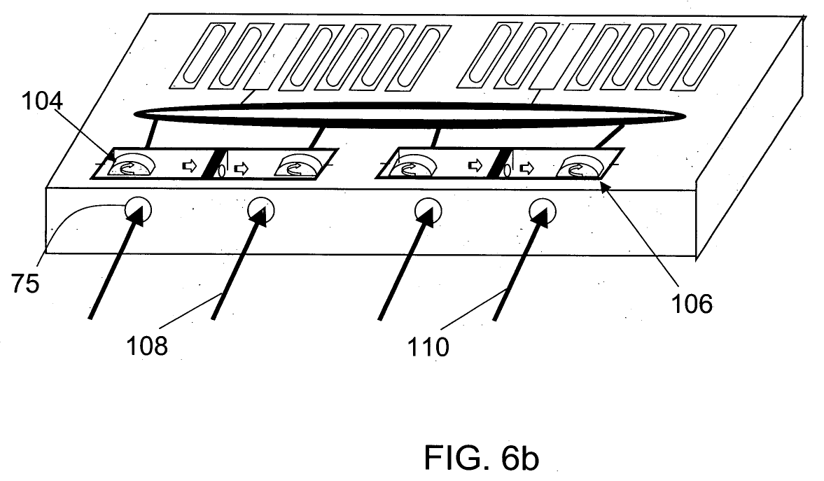

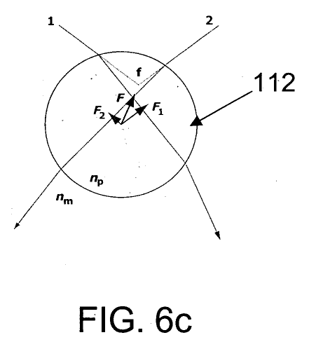

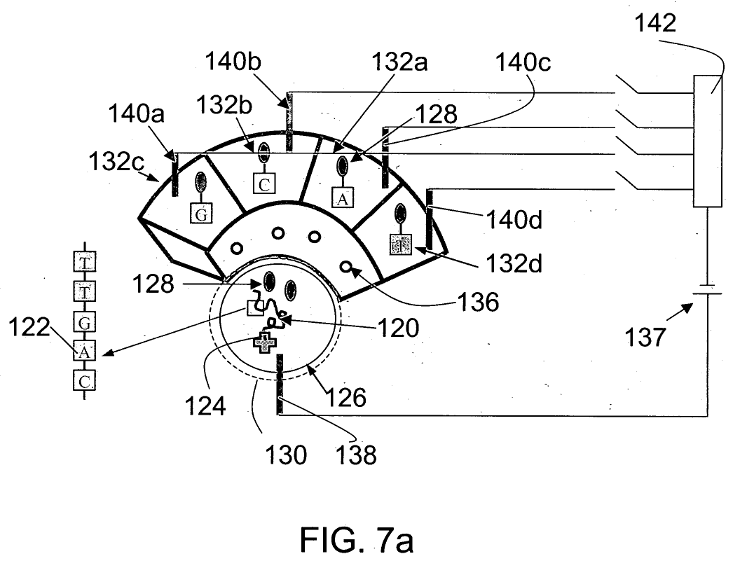

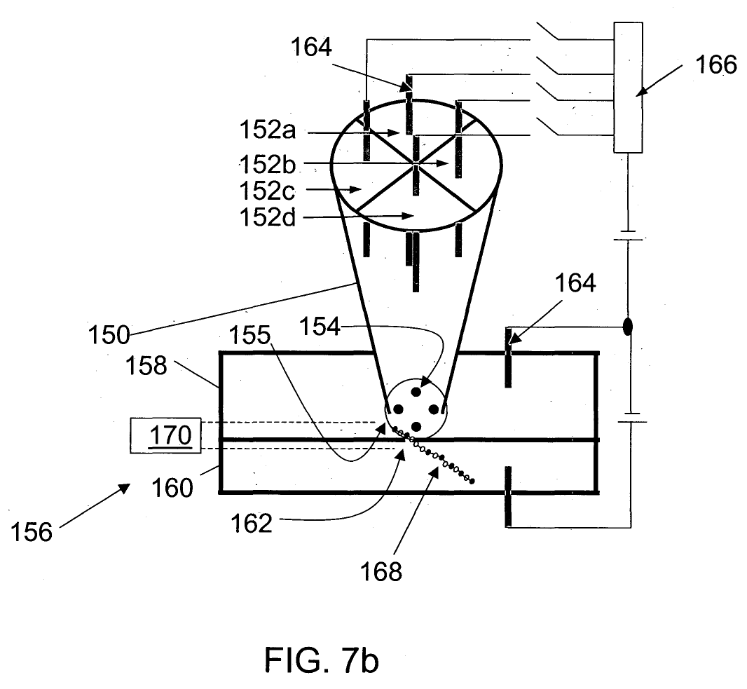

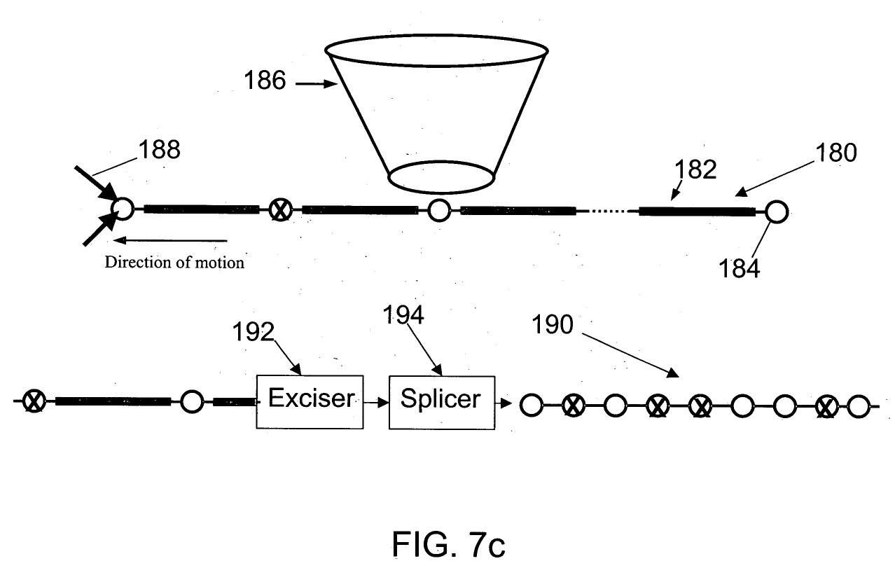

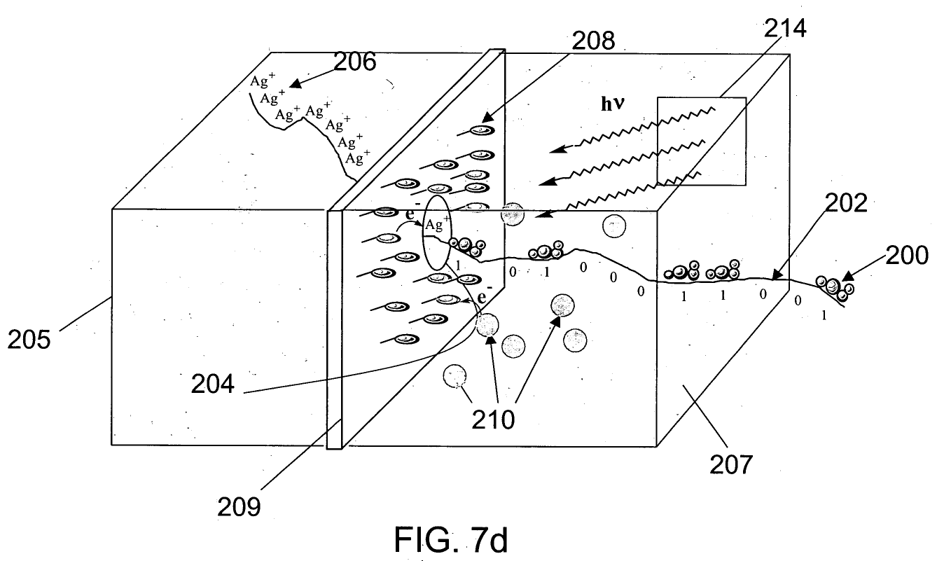

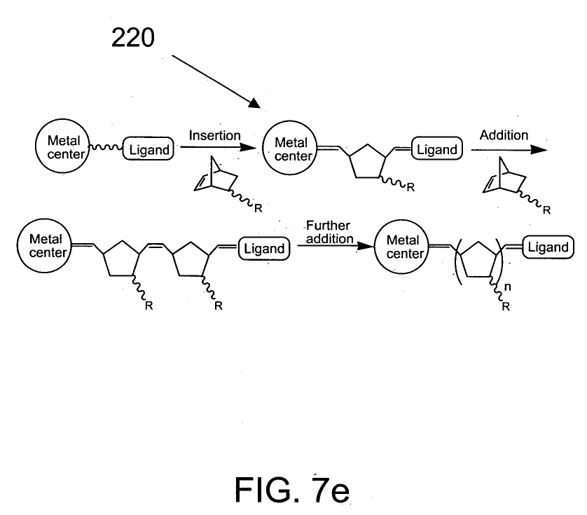

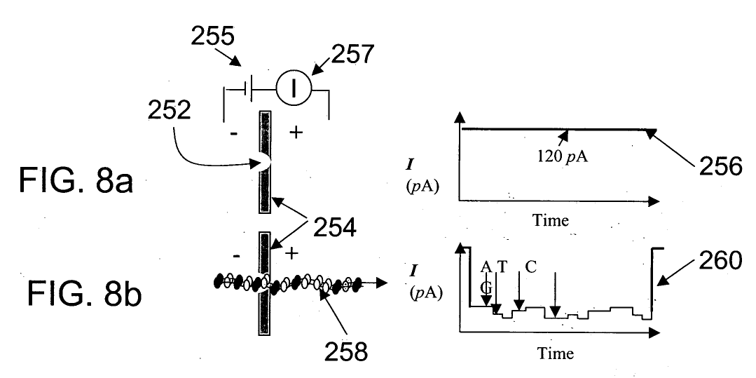

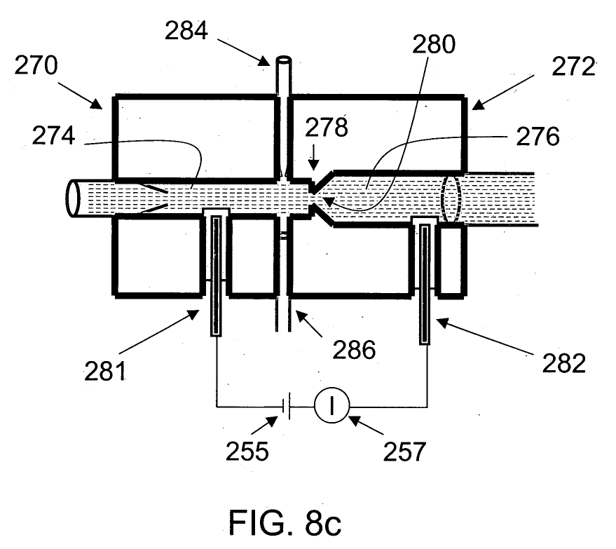

Storage device 51 includes a number of “parking lots” 52 for storing molecular strands 54 and a number of “actuated gates” 56 that control the strands entrance to and exit from respective parking lots 52. These gates have unique addresses and are controlled by an external signal via addressing lines (shown in FIG. 4b). A “race track” 58 is connected to parking lots 52 via actuated gates 56 and acts as a highway for transporting molecular strands. A “transport mechanism” 60, as shown in detail in FIGS. 6a-6c, moves the molecular strands 54 to and from the parking lots via the racetrack. In certain configurations, one or more “reservoirs” (not shown) are located on-device to store raw molecular material. In other embodiments the reservoirs may be off-device. A “write station” 64, as shown in detail in FIGS. 7a-7e, includes one or more actuated gates (“inlets”) for receiving raw molecular material, a write head that encodes a particular binary sequence into a strand and, in some cases, synthesizes the strand itself, and an actuated gate (“outlet”) connected to the racetrack. A “read station” 66, as shown in detail in FIGS. 8 through 10, includes an actuated gate (“inlet”) for receiving a strand from the racetrack, a read head for reading out the binary sequence from the strand, and one or more actuated gates (“outlets”) for destroying or reprocessing the strand or returning the strand to the parking lot. Access windows (see windows 75 in FIGS. 6a and 6b) are formed on the end of the device to allow focused laser beams 77 and 79 to interact with the molecules and strand in the read and write stations and perform the respective operations. To improve the stability of the stored data, zip units 76 implemented with various electrochemical gates would process the strand to create complementary double-stranded molecules for storage. Before readout, the double-stranded molecules would pass through an unzip unit 78 to split the strands apart. Depending upon the application, after readout the strands would be rezipped and stored.

Storage device 51 is formed on a substrate 80, suitably a rectangular piece of glass 2 cm long, 1 cm wide, and 0.1 cm thick. The top surface of the substrate is patterned (using electron beam lithography or similar methods) to provide ridges 82 and canals 84 that define parking lots 52 and racetrack 58 for the storage and manipulation of various strands (each strand is a physical data block, containing, for example, ˜7 Mbytes/cm). The strands are parked in the liquid-filled canals around the ridges. Typical width of each ridge and the separation between adjacent ridges is limited by today's e-beam lithography to perhaps around 100 nm. Parking lots are suitably 1 mm long, 10 microns wide and 1 micron deep.

When a strand is guided into the read/write block, it travels around the racetrack, passes under the read head, and its information content is converted to an electronic signal. The write head has the electro-opto-chemical machinery to create arbitrary sequences of bases, e.g. A, C, G, T molecules for DNA and string them together to form strands of desired length or to modify existing strands to encode the data. The write head is only needed in a Write-Once or Rewritable storage device, whereas the read head is essential for any kind of device, whether it is Read-Only or Recordable.

The network of liquid-filled canals 84 and the addressing lines 86 that control the actuator gates to route strands through canals are shown in more detail in FIG. 4b. The addressing lines are formed on a control wafer 87 using, for example, standard CMOS processing that is mounted on top of the device. As was mentioned above, the read and write heads remain stationary and the media moves around in the system. Transport mechanism 60 causes either the liquid, hence the strand to flow through the canals or directly moves the strand through the liquid. In this embodiment, the addressing lines control the actuator gates of all the parking lots such that a single parking lot is coupled to the racetrack and either the read or write head to form a “closed-loop” in which the strand flows through the liquid-filled canals to and from the read/write station and the addressed parking lot.

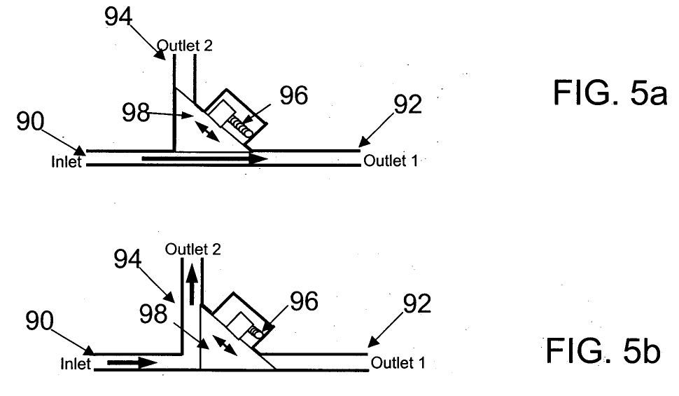

In this configuration, binary micro-fluidic valves 88 (shown in FIGS. 5a and 5b), which form the actuator gates, are placed at each end of each of the sixteen parking lots. The four address lines, which can address 2⁴=16 addresses, switch the valves to insert the addressed parking lot into the closed loop. 16 parking lots are used only as an example, in practice, millions of parking lots can be placed on a few centimeters squared area of a chip. The number of address lines required will be base 2 logarithm of the number of parking lots. The binary valves channel the incoming liquid at an inlet 90 toward either a first outlet 92 or a second outlet 94. An electric command signal is applied via the address line to compress a spring 96 and pull a switch block 90 to a lower position and direct the flow to the second outlet. When the command signal is removed, the spring relaxes to its initial state, thus redirecting the flow toward the first outlet.

Transport Mechanism

The strands may be moved through the liquid canals using a number of techniques including forming an electric field gradient in the canals in combination with charged strands, micro-fluidic pumps, and optical tweezers.

Transport Mechanism 1

As shown in FIG. 6a, the placement of negative and positive electrodes 100 and 102 on the substrate creates an electric field gradient throughout the “closed loop” liquid-filled canals. In this case, the negative electrode 100 is device ground and the positive electrode is placed at one end of the racetrack. The electrode could be placed elsewhere in the network. Voltage is applied to the electrodes via the control wafer (not shown). In order for the electric field gradient to transport the strand, the molecules must be charged. The presence of a free charge in an electric field produces a force that causes the strand to move. Certain molecules such as DNA are naturally charged. For other molecules, charge can be applied directly to the molecules during the write operation or, similar to pharmaceutical drug delivery techniques, the molecules can be wrapped in a lipid membrane, which is then charged.

Transport Mechanism 2

As shown in FIG. 6b, the placement of micro-fluidic pumps 104 and 106 in the read and/or write station chambers cause the pumps when addressed by focused laser beams 108 and 110 through windows 75 to rotate and pump the liquid in the canals. The liquid flows in the “closed-loop” carrying the desired strand to and from the read/write stations and the addressed parking lot. The pumps may be placed elsewhere on the device but the read/write chambers are convenient because they provide laser access.

Transport Mechanism 3

The transport mechanism may also be implemented using optical tweezers, which can move very small particles immersed in liquid-filled channels. As illustrated in FIG. 6c, by attaching one end of a macromolecule to a submicron-sized polystyrene particle 112 and gripping it with optical tweezers, the macromolecule and the particle can be moved in desired directions. A low power CW laser focused through a high-NA objective lens can trap non-absorbing particles a few microns in diameter. The particle, trapped at the focus of the objective, can be moved around by translating either the laser or the stage. The system thus acts like optical tweezers. Two rays, 1 and 2, of a laser beam are focused at F. Upon illuminating a dielectric particle with refractive index nₚ greater than the refractive index nₘ of the surrounding medium, the light rays are refracted. The changes in the light momentum for the two rays result in forces F₁ and F₂ on the particle 112. The sum of these forces, F, in a focused laser beam drives the particle back into the focus.

Write Mechanism

The write mechanism fundamentally encodes the binary data into a strand or macromolecule. In Write Mechanisms 1, 2 and 5, the raw media is provided as bases and the write head synthesizes the bases to form the strand and thereby encode the data. In Write Mechanisms 3 and 4, the raw media is provided as blank strands and the write head modifies the strands to encode the data. In Write Mechanisms 1, 2, 3 and 5 below, the data is encoded in the base-sequence of the strand itself. In Write Mechanism 4, the strand serves as a support structure on which the data is written.

Write Mechanism 1

A scheme for synthesizing macromolecules of arbitrary base-sequence in-situ is shown schematically in FIG. 7a. This is essentially a miniaturized and automated version of the process used in Gene-Chip fabrication. A short strand 120 of the polymer (containing no information at all) is needed as a seed molecule to initiate the recording process, whereby individual base units 122 are, added sequentially to the free-end of the seed molecule. The seed is attached to an anchor 124 at the center of the Write Station to prevent it from drifting away.

The various base molecules (i.e., A, C, G, and T in the case of nucleic acids) are kept within specific reservoirs 132a, 132b, 132c and 132d, respectively, and blocked by blocking group 128 that prevents the growth of the molecule beyond a single base during each visit to the reservoir. The reservoirs are connected to a main chamber 130 through a nano-pore 136 and the opening of each nano-pore, e.g., by the application of a proper voltage 137 between the reservoir and the main chamber via electrodes 138 and 140a-140d and switch 142, causes the free-floating end of the molecule 120 to enter the selected reservoir 132. Once within the reservoir, a single base is added to the free-end of the molecule, but further growth is prevented by the presence of the blocking group 128. The molecule 120 is subsequently extracted from the reservoir 132 by pulling it out through the nano-pore 136 and returned to the main chamber 130, where a mechanism such as a laser beam 126 removes its blocking group 128 in preparation for entry into the next reservoir 132. In this way the macromolecule is built up, one base at a time, through a programmed process of visiting a selected reservoir, returning to the main chamber for removing the blocking group, and repeating the process until the desired macro-molecular length is achieved.

The achievable macro-molecular length in the above process is unlimited because, unlike the method of oligonucleotide fabrication commonly-practiced in Gene-Chip technology, no capping groups (for the purpose of preventing error propagation through the sequence) are needed here. Error-correction coding, as commonly used in data storage systems, may be employed to render “tolerable” those fabricated molecules whose base-sequence deviates (albeit with small probability) from the desired ideal sequence.

Write Mechanism 2

Another proposed scheme for synthesizing an arbitrary base-sequence of DNA is depicted schematically in FIG. 7b. The setup consists of a conical chamber 150 containing four isolated sections 152a, 152b, 152c and 152d. Each section has a small hole 154 at the bottom (˜100 μm in diameter), over which lipid bilayers can be painted to form a lipid membrane 155. An α-hemolysin-based nano-pore, for example, is subsequently inserted into each of the four apertures. The conical chamber is placed in a small tank 156 partitioned into an upper chamber 158 and a lower chamber 160. The partitioning wall has another small hole in which a nano-pore 162 embedded in lipid membrane 155 has been inserted. All four sections of the conical chamber as well as both sections of the tank are filled with a buffer solution. The sections of the conical chamber contain the A, T, G, C nucleotides, respectively. Six Ag—AgCl electrodes 164 connected to control circuitry 166 are placed within the buffer solution of the six sections.

To write an arbitrary DNA sequence 168, a series of electrical pulses are applied between the various electrodes of the four chambers (containing A, C, G, T nucleotides) and the upper section of the tank. This will inject various nucleotides in a desired sequential order into the tank. A successful injection is registered by a drop in the corresponding ionic current and picked up by a monitoring station 170, thus serving as a feedback signal to close the gate until further notice. The joining of the injected bases to the growing macromolecule located in the upper chamber of the tank is accomplished by means of enzymes floating in the same chamber. If necessary, the process can be assisted or accelerated by photons and electrical signals.

The process continues until the desired length of the DNA molecule 168 is created. The newly-formed strand is then transferred to the lower chamber for further processing and subsequent transfer to a parking lot. When required, this strand can be proof-read by a monitoring station 170 while translocating across the nano-pore on the partition wall between the upper and lower chambers of the tank.

As for enzymes that could perform the aforementioned task of attaching individual nucleic-acid bases to the growing DNA strand, it is well-known that DNA polymerase, reverse transcriptase, and telomerase are enzymes that carry out exactly the same task within the confines of biological cells. In all cases, however, there exists a template (e.g., complementary DNA or RNA), on which the new bases are added in the form of complements to those already residing on the template. Telomerase incorporates within itself a template of a short sequence of bases, which it repeatedly adds to the end of chromosomes. Suppose now that four groups of enzymes are floating around in the upper chamber of the tank. Each enzyme carries within it a template for a single base, i.e., G, C, A, or T. When a single nucleotide base is released into this chamber, the enzyme having the complementary template will grab it bring it to the growing end of the DNA molecule, and attaches it to this growing molecule. It is not known exactly how telomerase is able to find the chromosomes and start to do its job, but the chambers are comparable in their dimensions to biological cells, and by creating the right chemistry in the chamber the individual enzymes will be enticed to look for the complement to their own (internal) template, then transfer the complementary base to the end of the growing molecule.

Assuming that it is possible to clearly distinguish individual bases by measuring the differential ion-current through a nano-pore, it might become feasible to apply a modulated potential that could hold a DNA strand threaded through a nano-pore at a specific base unit. This would provide a means of localizing the active chemical site at a well-defined point in space. Additionally, the enzymes needed for the base insertion chemistry could be attached to the α-hemolysin proteins via a long tether, which would hold them in close proximity to the pore while, at the same time, prevent the enzyme and the pore from interfering with each other's activity. The chemistry would then proceed more rapidly as the kinetics would no longer be limited by the diffusion rates of the enzymes and the DNA molecule. The chemistry would be further accelerated if the bases being added could be delivered in the vicinity of the localization site.

The chemistry of artificial base-insertion (for instance, in Gene-Chip technology) often involves some sort of capping group. As related to the present data storage device, a modified capping group that is too large to pass through the nano-pore could be used. A starter DNA-strand bearing a cap on one end could be threaded through the pore. Once through (as indicated by the ion current), the other end of the strand would be capped. The ssDNA would then be trapped in the pore. The read process would follow as described below. Writing would involve insertion of new base units already attached to the same capping group, thus resulting in the new end of the growing molecule being continually terminated by the large capping group. The insertion chemistry in this case can be accelerated as detailed above, and possibly may be more site-specific if the ssDNA can be held in the pore by a holding-potential with only the capping group and the final base in the strand protruding from the pore.

The above write scheme is a specific example of a microfluidic reactor. More generally a microfluidic reactor may be comprised, of a number of the following components, which may be fabricated using two-photon and/or conventional lithographic techniques: (i) reservoirs for volumes of protected nucleotide solutions, deprotecting reagent, rinse solution, and solution waste; (ii) micro-pumps or valves to control the flow of the protected nucleotides in the microflow system; (iii) microfluidic channels that connect the various components; (iv) a reactor comprising a chamber with provisions for surface attachment of nucleotide strands or a supported nano-pore which can be used to hold and translocate DNA oligomers undergoing synthesis; (v) a chamber for purification and possibly recycling of nucleotide and rinse solutions; and (vi) electronics that control the pumping of flows, valve actuation, translocation of the strand in the nano-pore, and monitoring of the current through the nano-pore to, for example, ascertain the fidelity of the written sequence.

The nano-pore can be surface functionalized with enzymes of the type needed to catalyze the condensation of nucleotide phosphoester linkages and other groups which can be used to cause deprotection of protected nucleotides. In the case of an α-hemolysin nano-pore, the α-hemolysin proteins themselves can be functionalized using standard protein labeling and functionalization schemes, such that the catalysts and protection/deprotection agents discussed above are covalently bound to the protein and thus are held in close proximity to the nano-pore site and the reacting end of the DNA strand being synthesized. The nano-pore can thus act as a “solid-support” for the DNA strand under synthesis, where the strand is held in the pore by an appropriately modulated potential.

Write Mechanism 3.

A technique for modifying the base-sequence of a blank strand is depicted in FIG. 7c. A long precursor strand 180 consisting of relatively long, inert segments 182 separating individual active molecules 184, which are identical in their native (or ground) state, is exposed to an activator 186. The inert segments simply act as spacers to create a reasonable distance between adjacent active molecules.

The activator 186 may be a tightly focused laser beam, a localized electric field, a tunneling electrode, an anchored enzyme, etc. The strand is pulled by a micro-machine 188 under the activator; for instance, optical tweezers may be used to drag the strand from right to left.

Whenever the activator is energized, the active molecule exposed to this activator at that moment will be transformed from its native state to a (physically or chemically) different “excited” state, shown as circle with an “X”. The native (ground) state and the transformed (excited) state of the active molecule must be stable; they must also be distinguishable from each other through the mechanism employed in the read station.

Once the entire strand 180 is written, that is, its active molecules are selectively converted from ground to excited state, an exciser 192 removes the inert spacer molecules 182 from the strand and a splicer 194 splices the active molecules spliced together in the same order in which they were placed at the end of the writing process to form strand 190. In some cases, the initial strand may not include inert spacer molecules in which case the exciser and splicer are not required.

The recorded strand 196 thus created represents a binary sequence, whereby the ground state of the active molecule represents the binary digit “zero”, and the excited state represents “one,” or vice versa. If active molecules having more than two stable states are embedded in the precursor strand, non-binary (e.g., ternary, quaternary) recording will be possible as well.

The recorded strands will be “erasable” if the excited state(s) of the active molecule can somehow be reversed; otherwise the recorded strand will be an example of a write-once storage medium. In the latter case, however, erasable or rewritable data storage will still be possible in the following sense: any recorded strand that is no longer needed will be removed from its parking lot and destroyed (or abandoned), and a new precursor strand is written with fresh data, and stored in the same physical location (i.e., parking lot) from which the abandoned strand had been removed.

The inert spacer molecules are needed in the above scheme only if the dimensions of the activator (i.e., the write head) are greater than those of the active molecule. In the case of an ultra-violet (UV) activator of wavelength λ=200 nm, for example, if far-field optics are used to focus the beam, the diameter of the focused spot cannot be much smaller than 100 nm. Since typical active molecules have dimensions on the order of 1 nm, the required spacer molecules must be at least 100 nm long. With near-field optics, it is possible to confine the optical activators to sub-wavelength dimensions, thereby reducing the required length of the spacer molecules. Electric-field or tunneling-tip activators may require even shorter spacers.

Write Mechanism 4

Yet another writing scheme is to take a blank strand and grow nanoclusters on selected bases to encode the data. In this case, the base-sequence of the strand is not encoded but rather used as a support structure.

This scheme grows small metal nanoclusters 200, with a diameter of, for example, 10 nm or less, at defined positions along a DNA or RNA single or double strand 202 as a means of storing information on the chain as shown in FIG. 7d. The presence or absence of the metal cluster will represent a “1” or a “0” bit, respectively, at that location. The increase in the cross-sectional area at the positions of the nanoclusters will lead to a substantial contrast of the ion current when a nanocluster bound to the chain is passing through a lipid nano-pore channel compared to when a non-cluster labeled portion of the chain passes through.

One approach for “writing” of metal cluster bits on a polynucleotide chain is an extension of a method reported by Braun et al. Nature, 391, 775-778 (1998)for the DNA-templated growth of silver nanowire's. In this work, a 12 μm gap between metal electrodes was spanned by single DNA strands of ˜10⁴ nucleotides (nt) that were attached by hybridization to complementary oligonucleotides anchored to the electrodes. The DNA strand was coordinated to Ag⁺ ions via Ag/Na⁺ ion exchange and complexation to the bases. The Ag⁺ ions were then reduced in the presence of AgNO₃ by using hydroquinone under basic conditions leading to the formation of very small clusters of silver along the DNA chain. In a following development step, further reduction of AgNO₃ with hydroquinone under acidic conditions was performed resulting in a DNA strand well coated with interconnected silver nanocrystals which formed a conducting nano-wire with a diameter of 100 nm, as evidenced by AFM and I-V measurements.

This work demonstrates the templated growth of silver nanowires on a DNA chain. The reduction of silver ions complexed to a DNA chain are applied to form localized domains of small silver nanoclusters in controlled positions along the strand for the purpose of encoding information along the chain.

A new approach for encoding information onto a polynucleotide chain is controlled photoreductive growth of metal nanoclusters, such as silver nanoclusters, in discrete locations on the chain during the process of translocation through an ion-channel 204, as illustrated in FIG. 7d. As an example, a polynucleotide strand 202 will be complexed to Ag⁺ 206 in a chamber 205 and translocated from the cis side to the trans side of the transmembrane channel into chamber 207. The chamber wall 209 on the trans side of the ion-channel is chemically modified with surface attached photosensitizer groups 208 that are capable of reducing Ag⁺ from the excited state but not from the ground state by thermal reaction. Such groups would include rhodamine dyes and related cyanine dyes that are chemically functionalized for surface attachment. Such dyes are available with isothiocyanate groups that can react with surface bound amino groups to form stable thiocarbamate linkages. Depending upon the compartment wall material, various chemistries including but not limited to trichlorosilane reactions with surface hydroxyl groups, thiols binding to gold or silver surfaces, ester bond formation via reactions with surface hydroxyls or active ester groups, or amide bond formation via reaction with amines with surface active ester groups can be used to attach reactive species bearing amino groups to the surface for subsequent assembly of photosensitizers on the surface. Other means for attachment of molecules to surfaces, which can be used to place photosensitizers on the surface, are well known to those skilled in the art and include for example, those involving biomolecular recognition processes such as biotin binding to avidin or streptavidin. In the trans compartment an excess of buffered AgNO₃ will be maintained.

Upon detection of a change in ion current signifying the initiation of translocation, the trans side of the channel will be irradiated with a short laser pulse (<1 μs duration) corresponding approximately to the residence time of a nucleotide in the channel. The laser pulse excites the photosensitizers on the surface and activates reduction of Ag⁺ ions to Ag⁰ atoms. The estimate is that (with reasonable coverage of the surface with sensitizers and excitation efficiency) on the order of thousands of atoms can be generated, and this can be controlled with the fluence of the light pulse. The generated atoms in solution will diffuse and some will encounter the translocating chain at the exit of the channel leading to the formation of small silver metal clusters 200 bound to the chain 202. The generation of Ag atoms will be concentrated near the trans chamber wall because of the spatially fixed positions of the photosensitizers on the wall.

Generated atoms that do not react with the chain can diffuse away and become scavenged or may be able to react with the translocating chain at a distance from the channel exit. However, the concentration of the photogenerated atoms will be falling off cubically with distance away from the channel exit, so the reaction will be largely confined to a small length along the chain. Rough estimates suggest that the labeling of the chain with clusters would be limited to ˜10 nm. After excitation and reduction of metal ions, a fraction of the surface attached sensitizers will become oxidized and these will be reduced to their original state with sacrificial electron donors 210, sustained at moderately high concentration, in solution in the trans chamber. Given the estimate of the size of the bit, the shortest time interval between laser pulses will be ˜10 μs. The system will be irradiated with light pulses 212 through a window 214 that are clocked in a sequence corresponding to the bit stream to be encoded while the chain is being translocated, leading to a pattern of deposited silver nanocrystals along the chain. Additional agents may be needed to protect nanoclusters deposited on the oligonucleotide chain to prevent agglomeration of nanoclusters located at different positions along the chain. Thiols including but not limited to 3-mercaptoproprionic acid can be used to passivate the surfaces of the nanoclusters with respect to aggregation while also imparting improved water solubility to the clusters. Upon exiting from the channel, the encoded chains will be stored. for subsequent retrieval and readout of information by measurement of the ion current upon translocation through an ion-channel read chamber. The polymer backbones of this invention are not limited to the use of polynucleotides. Other polymer backbones, especially polyanionic polymers capable of binding metal ions, such as silver or gold, can be used as a macromolecular recording template for the writing of metal nanoclusters. An approach to synthetic polymer backbones that can be employed in this invention is described in the following section.

Writing Mechanism 5

The invention is not limited to encoding information solely on DNA-like polymers. Many other polymeric systems could be used as the information storage system. For example, data could be written onto polymers which are constructed by ring-opening metathesis polymerization (ROMP). Examples of ROMP chemistry are well described in the literature (see for example: C. B. Gorman et al., Synth. Met. vol. 41-43 (1991) 1033; D. M. Lynn et al, J. Am. Chem. Soc., vol. 122 (2000) 6601; P. Bissinger, U.S. Pat. No. 6,075,068). Several transition-metal catalysts are well known for their ability to initiate “living” ROMP polymerization. Typically, these systems consist of a coordination complex for which one of the ligands is weakly bound to the active metal center and is easily displaced by a monomer such as a strained cyclic polyene. The polyene monomer becomes bound to the metal center, inserting at the active metal-ligand site. Additional polyene-cycles can also insert at the first metal-polyene site, and this process may continue resulting in a growing polymer chain. Such systems are designated as living because the catalytic center tethered at the end of the growing polymer remains active and will continually add additional monomer units as they become available.

Data can be encoded by catalyzed ROMP 220 as illustrated in FIG. 7e. Data “bits” would be in the form of functionalized cyclic polyenes, where the nature of the pendant “R”-group differentiates the bit-type. The R-groups may also bear a formal charge (particularly if deprotonated or otherwise deprotected), so that the polymer backbone acquires an electrostatic charge with which, through the application of potentials, it can be shuttled around a microfluidic reactor system and through nano-pores. The spectator ligands bound to the catalyst can also be functionalized so that the catalyst acquires sufficient steric bulk that it acts as a capping group that prevents a data-strand from passing completely through a nano-pore. The position of the data strand can then be maintained at a nano-pore site, which affords a level of control on the molecular data system.

A wide range of R-group-pairs could be used to distinguish between the bit-states “0” and “1”. In the preferred embodiment of the invention, the R-group pairs would be sufficiently different so as to confer a clearly detectable physical or chemical property at each position along the polymer chain, thereby enabling the bit-state to be distinguished at the read-station. The R-group-pairs could include, but are not limited to, the examples listed below, wherein a mechanism is identified by which they could be distinguished at an appropriately configured, read-station, such as a translocation-nano-pore as described below:

(a) R═H or a porphyrin macrocyle, where the two may be distinguished by the difference in their steric bulk, particularly upon translocation through a nano-pore;

(b) R═H or a phthalocyanine macrocyle, where the two may be distinguished by the difference in their, steric bulk, particularly upon translocation through a nano-pore;

(c) R═H or a fullerene moiety (e.g. C₆₀, where the two may be distinguished by the difference in their steric bulk, particularly upon translocation through a nano-pore;

(d) R═H or a high-generation dendrimer, where the two may be distinguished by the difference in their steric bulk, particularly upon translocation through a nano-pore;

(e) R═H or a carboxylic acid group (—CO₂H), where the two may be distinguished by the difference in their hydrogen-bonding capability, acidity, polarity, or electrolytic conductivity, or by the differences in their nano-pore translocation times brought on by hydrogen-bonding, electrostatic, or other interactions of the carboxylic acid group with functionalities in the nano-pore;

(f) R═H or a sulfonic acid group (—SO₂OH), where the two may be distinguished by the difference in their hydrogen-bonding capability, acidity, polarity, or electrolytic conductivity, or by the differences in their nano-pore translocation times. brought on hydrogen-bonding, electrostatic, or other interactions of the sulfonic acid group with functionalities in the nano-pore;

(g) R═H or a chromophore (e.g. a porphyrin macrocycle, phthalocyanine macrocycle, rhodamine derivative, xanthene derivative, or other π-conjugated fragment), where the two may be distinguished by the difference in their polarizability or their photoemissive properties, or by the differences in their nano-pore translocation times brought on by π-stacking, induced-dipole, or other interactions of the chromophore with functionalities in the nano-pore;

(h) R═H or a short ssDNA sequence, wherein the two may be distinguished by the difference in their nano-pore translocation times brought on by electrostatic or hydrogen bonding interactions, or by base-pair matching of the ssDNA sequence with a complementary strand that is covalently bound to the nano-pore opening (see for example S. Howorka et al., Nature Biotechnol., 2001, vol. 19(7), pp. 636-639).

Read Mechanism

A single-strand (ss) sequence is read out by detecting the bases either individually or collectively, depending upon the precision of the read head, to read out the binary data directly from the strand. The ability to detect a distinct base or the state of a base directly rather than using traditional optical or magnetic read-out techniques greatly enhances the storage capacity of the device.

Read Mechanism 1

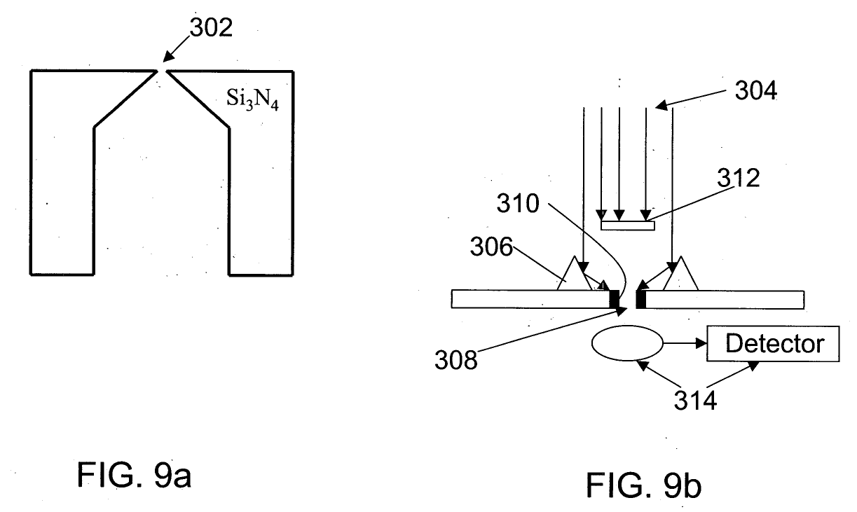

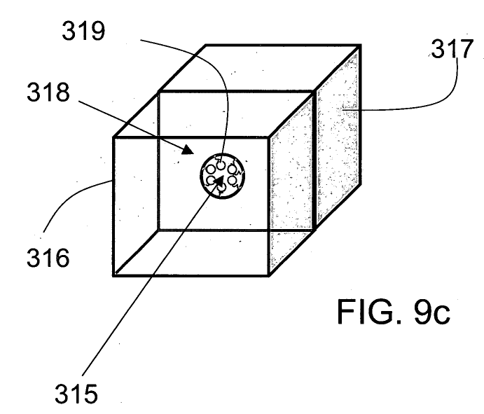

As illustrated in FIGS. 8a-8c and 9a-9c, one approach is to translocate the strand through a nano-pore while monitoring the change in the electrolytic current through that pore. A typical pore created by seven molecules of a-hemolysin protein embedded in a lipid bilayer is ˜2.6 nm in diameter. Due to the polar nature of the nucleotides, translocation of the DNA can be accomplished under an applied electric field. A schematic of the translocation process 250 through a nano-pore 252 is shown in FIGS. 8a and 8b.

As shown in FIG. 8a, nano-pore 252 is created in a lipid bilayer 254 by α-hemolysin proteins. The bilayer separates two sections of a buffer solution (1M KCl: 10 mM-HEPES/KOH). Application of 120 mV across the bilayer by a voltage source 255 causes 120 pA of ionic current to flow through the nano-pore as measured by current meter 257 and shown in the current vs. time plot 256 on the right side of the figure. As shown in FIG. 8b, when a DNA strand 258 passes through the nano-pore 252, it partially blocks the ionic current. As different nucleotides pass through the nano-pore, they hamper the flow of the ionic current differently as reflected in the current vs. time plot 260 on the right-hand side. Fluctuations in the amount of current blockage are due to differences in the size and/or the electronic charge of the various nucleotides. Given a sufficient signal-to-noise ratio, the base sequence of the translocated DNA molecule can be uniquely identified by analyzing the temporal evolution of the electrolytic current signal.

The heart of the readout system is the nano-pore through which translocation of the encoded strand occurs. In the current experimental system this nano-pore is formed by the spontaneous formation (self assembly) of seven units of the α-hemolysin ion-channel-forming protein. A single pore is subsequently incorporated in a bilayer membrane separating the cis and trans chambers of the Read Station.

FIG. 8c shows a specific design for read chambers 270 and 272 that are formed within PDMS material in this manner. The chambers and the passageways for the electrodes are made by placing tungsten wires of appropriate diameters into liquid PDMS, heating the liquid PDMS for several hours until it solidifies, and then removing the tungsten wires. The horizontal chambers 274 and 276 on the left- and the right-hand side in FIG. 9a indicate the main chambers for conducting DNA translocation through a nano-pore, which nano-pore will be fabricated in a lipid membrane 278 placed across the narrow passway 280 that connects the two chambers. A pair of silver/silver-chloride electrodes 281 and 282 are inserted from the bottom and make contact with the liquid inside the two chambers. A voltage applied across the electrodes by voltage source 255 creates an ionic current through the nano-pore that is measured by current meter 257. Partial block of the nano-pore by the bases in the strand modulates the current. Tubes 284 and 286 at the top and the bottom of the left-hand chamber are for adding to or removing from the chamber various fluids, protein molecules, etc.

This design is functionally similar to other designs for performing DNA readout.(i.e., translocation) experiments using micro-chambers and nano-pores. The advantage of the system of FIG. 8c is that it can-be made very small (chamber diameters on the order of 100 microns) compared to other designs, although, functionally speaking, all these designs are similar. They all have two-chambers separated by a hole that supports the lipid billayer, a nano-pore inserted into the lipid membrane, electrodes in contact with the liquids in both chambers, and means for filling the chambers with liquids, removing undesirable liquids from the chambers, adding protein molecules or DNA strands to the chambers, and so on.

In a practical device, it would be desirable to have a robust solid-state nano-pore having dimensions comparable to the ion channel. An idealized cross-sectional view of a solid-state pore 302 is shown in FIG. 9a.

A method of fabricating nanometer-sized holes in solid substrates starts with an optical pinhole a few microns in diameter. With reference to FIG. 9b, a beam 304 of argon ions (Ar⁺) is made to impinge on glass prisms 306 kept in the vicinity of the pinhole 308. The ion beam sputters material 310 from the glass prisms, which deposits on the periphery of the pinhole and begins to fill it up. The Ar⁺ beam is prevented from striking the pinhole directly by placing a beam stop 312 immediately above the pinhole. However, a small number of ions do make it through the hole and are detected by the detector 314 placed on the opposite side of the pinhole. The detector signal is a measure of the size of the pinhole. Once the detector signal reaches a certain level, the ion beam can be switched off.

In a truly integrated device, of course, the nano-pores must be fabricated in-situ, without the need for external adjustments and/or alignments. FIG. 9c is a schematic diagram showing an alternative method of creating a nano-pore 315 in the wall between two chambers 316 and 317 in-situ. The process starts with a fairly large hole 318 on the order of 10 microns in diameter, then begins to close the hole by depositing gold or silver nano-particles 319 on the inside walls of the hole using an electroless plating process. While electro-plating is in progress the hole size is monitored by measuring the electrical current through the (shrinking) pore. When the magnitude of the current indicates that the appropriate size for the nano-pore has reached, the electroless plating process is stopped, thus forming a nano-pore of desired size. This is an alternative approach to using lipid membranes and protein-based nano-pores that might have advantages in practice. Other solid-state or biological-based techniques, for forming the nano-pore in the wall between the two translocation chambers for readout (or writing) of macro-molecular data strings can-be used, and this disclosure is not necessarily confined to the aforementioned methods.

Read Mechanism 2

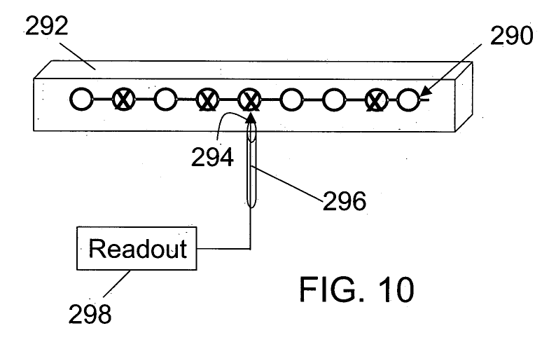

As illustrated in FIG. 10, another approach is to pass a strand 290 through a narrow chamber 292 so that the strand is well confined and passes very close to a microscopic probe 294 inserted into the chamber through a tube 296. The probe detects either the state of the base or the base itself, which is then read-out by a readout device 298. In one embodiment, the probe is a scanning tunneling microscope tip that produces a tunneling current between each base and the tip that is readout. In another embodiment, the probe is an atomic force microscope tip that deflects when held in close proximity to a base.

3D Storage Device

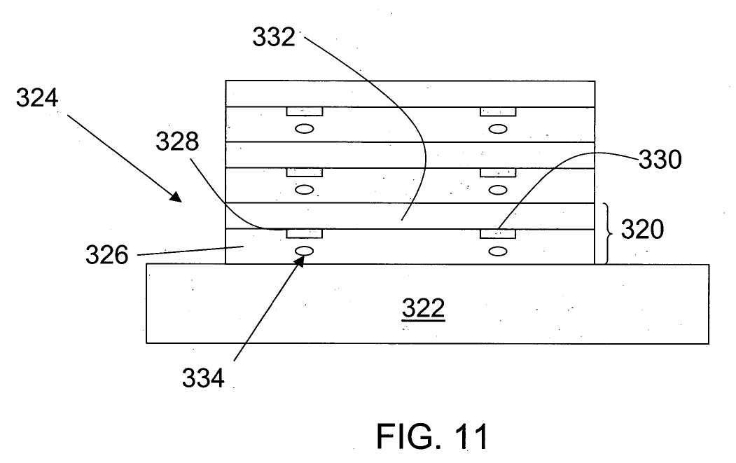

As shown in FIG. 11, storage devices 320 can be stacked one on top of another on a substrate 322 to form a 3D storage device 324 capable of having a volumetric density exceeding petabytes per cubic centimeter (PB/cm³). The substrate supports the otherwise fragile devices. Each storage device 322 includes a bio-mechanical wafer 326 that includes the parking lots, racetrack, actuator gates, transport mechanism, read and write stations 328 and 330, canal filling liquid and the molecular strands and a control wafer 332 that includes the addressing lines. In such a 3D configuration it is necessary that the laser access windows 334 are formed on the end of the bio-mechanical wafer to facilitate horizontal access.

Parallel Read/Write Stations

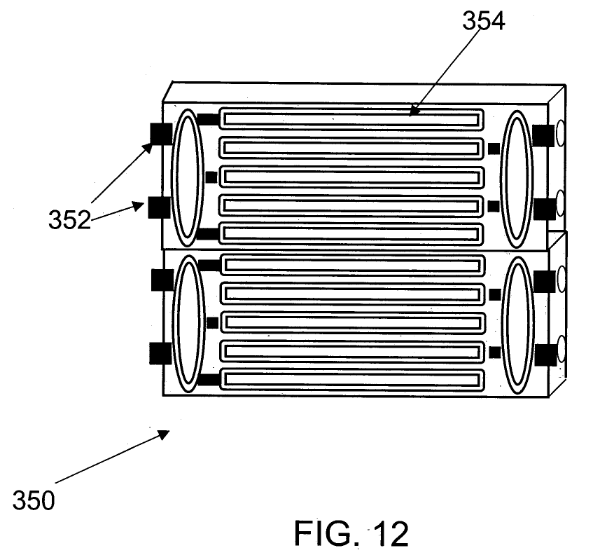

As shown in FIG. 12, a storage device 350 can be configured with multiple read/write stations 352 to access one or more blocks of parking lots 354 to provide a parallel read/write capability to reduce access time and increase throughput. The read/write stations can either address one shared block of parking lots, which increases flexibility, or they can address dedicated blocks which simplifies, addressing.

While several illustrative embodiments of the invention have been shown and described, numerous variations and alternate embodiments will occur to those skilled in the art. Such variations and alternate embodiments are contemplated, and can be made without departing from the spirit and scope of the invention as defined in the appended claims.

We claim:

1. A storage device, comprising:
a write head that encodes strands of molecular material with sequences of binary data;
a storage block for storing the strands;
a read head for reading out a sequence of binary data from a selected strand; and
a transport mechanism that moves the strands between the read and write heads and the storage block.

2. The storage device of claim 1, wherein the strand includes a number of molecular bases that are encoded with the binary data, said read head detecting each base or collection of the bases within the strand to read out the binary data directly from the strand.

3. The storage device of claim 2, wherein the read head comprises:
First and second chambers, which have a shared wall and contain a liquid,
A nano-pore in the shared wall;
A voltage source that applies a voltage across said first and second chambers thereby producing an ionic current that flows through the nano-pore and pulling strands through the nano-pore as they are presented to the first chamber; and
A current meter that measures fluctuations in the ionic current as each base or collection of bases in the strand flows through the nano-pore.

4. The storage device of claim 2, wherein the read head comprises:
A chamber that closely confines a strand as it moves therethrough, and
A microscopic probe held in close proximity to the passing strand such that the probe interacts with each base or collection of bases and produces a signal indicative of the binary data encoded therein.

5. The storage device of claim 4, wherein the microscopic probe comprises a scanning tunneling microscope tip, that produces a tunneling current between each base or collection of bases and the tip.

6. The storage device of claim 4, wherein the microscopic probe comprises an atomic force microscope tip that deflects when held in close proximity to a base or collection of bases.

7. The storage device of claim 1, wherein said read and write heads and said storage block are integrated, on a substrate, further comprising:
at least one reservoir of molecular material located off-substrate that feeds molecular,material to the write head; and
a dump located off-substrate for receiving the disposed strand.

8. The storage device of claim 1, wherein said read and write heads and said storage block are integrated on a substrate, further comprising:
at least one reservoir of molecular material located on the substrate that feeds material to the write head; and
a recycle unit located on the substrate for receiving the disposed strand, breaking the strand into molecules, and returning them to the reservoir.

9. The storage device of claim 1, wherein the storage block comprises:
a plurality of parking lots for storing the strands;
a respective plurality of actuated gates that control the strands entrance,to and exit from the respective parking lots and read and write heads, said actuated gates having unique addresses and being controlled by an external signal; and
a race track that is connected to the parking lots via the actuated gates and acts as a highway for transporting the strands.

10. The storage device of claim 1, wherein the write head receives blank strands and modifies the strands to encode the binary data.

11. The storage device of claim 1, wherein the write head receives distinct molecular bases and synthesizes them into strands to encode the binary data.

12. The storage device of claim 1, wherein the write head encodes the binary data into the base-sequence of the strand.

13. The storage device of claim 1, wherein the write head uses the strand as a support structure on which to encode the binary data.

14. The storage device of claims 11 and 12, wherein the molecular material includes at least two distinct bases, said write head comprising:
at least two reservoirs containing the different bases and a blocking group;
a main chamber coupled to the reservoirs by respective nano-pores;
an anchor in the main chamber for holding one end of a seed strand;
electrodes for applying a voltage between the main chamber and a selected reservoir to cause a free-floating end of the seed strand to enter the selected reservoir through its nano-pore where a single base and blocking group are added to the free-floating end of the seed strand and then to return to the main chamber; and
a mechanism that removes the blocking group from the seed strand in the main chamber to prepare the strand for entry into the next reservoir.

15. The storage device of claims 11 and 12, wherein the molecular material includes at least two distinct bases, said write head comprising:
a tank partitioned into an upper chamber and a lower chamber connected by a nano-pore, said chambers being filled with a buffer solution and said upper chamber containing enzymes for joining base units to a strand;
a chamber having at least two reservoirs containing different bases in a buffer solution, each reservoir having a nano-pore at one end placed in the upper chamber of the tank;
a plurality of electrodes positioned in the upper and lower chambers and the at least two reservoirs to apply a series of electrical pulses that inject bases from their respective reservoirs into the upper chamber where they are sequentially joined to the strand to encode the sequence of binary data and, once encoded, that transfer the strand to the lower chamber.

16. The storage device of claim 15, further comprising:
a monitoring station that senses the injection of a base into the upper chamber and closes the nano-pores so that only one base is joined to the strand at a time and senses the strand as it passes from the upper chamber through the nano-pore to the lower chamber to ensure, that the strand represents the sequence of binary data.

17. The storage device of claims 10 and 12, wherein the blank strand comprises molecular bases having at least two states, the write head comprising:
an activator that transforms the bases into one of its states; and
a transport mechanism that pulls the strand past the activator to write the sequence of binary data into the strand.

18. The storage device of claim 17, wherein the blank strand comprises inert segments that separate the bases, the write head further comprising:
an exciser that removes the inert segments from the strand after,the bases have been activated; and
a splicer that splices the active molecules back together into the strand.

19. The storage device of claims 10.and 13, wherein the write head comprises:
a first chamber having a strand of molecules and nano-particles;
a second chamber having an access window, a chamber wall separating said first and second chambers having an ion-channel formed therein with the,trans side of the wall being chemically modified with surface attached photosensitizer groups capable of reducing the nano-particles;
a transport mechanism for pulling the strand and nano-particles through the ion-channel; and
a laser that emits pulses through the access window to excite the photosensitizers and activate reduction of the nano-particles to form nano-clusters bound to the strand at selected locations to encode the sequence of binary data.

20. The storage device of claim 19, wherein the nano-particles are Ag+ ions.

21. The storage device of claims 11 and 12, wherein the write head writes the, binary data sequence into a strand using a ring-opening metathesis polymerization (ROMP) process.

24. The storage device of claim 1, further comprising a plurality of said read and write heads that address the storage block in parallel.

25. The storage device of claim 1, wherein the strands are electrically charged, said transport mechanism comprising a pair of electrodes that establish an electric field gradient that pull the strands around.

26. The storage device of claim 1, wherein the transport mechanism comprises a laser that forms optical tweezers that grab the strand and pull it around.

27. The storage device of claim 1, wherein the strands reside in a liquid, said transport mechanism comprising one or more micro-fluidic pumps that induce a flow current in the liquid that moves the strand.

28. The storage device of claim 1, wherein the molecular material is DNA having bases of adenine (A), thymine (T), cytosine (C) and guanine (G).

29. The storage device of claim 28, further comprising a zip unit the forms a double-helix of the DNA strand for storage and an unzip unit that extracts the single strand for the read head.

30. The storage device of claim 1, wherein the molecular material is RNA having bases of adenine (A), uracil (U), cytosine (C) and guanine (G).

31. A storage device, comprising:
a plurality of parking lots for storing molecular strands;
a respective plurality of actuated gates that control the strands entrance to and exit from the respective parking lots, said actuated gates having unique addresses and being controlled by an external signal;
a race track that is connected to the parking lots via the actuated gates and acts as a highway for transporting molecular strands;
a transport mechanism that moves the molecular strands to and from the parking lots via the racetrack;
a write station that includes at least one inlet for receiving molecular bases, a write head that synthesizes the bases into strands in-situ to encode a particular binary sequence in a base-sequence of the strand, and an outlet connected to the racetrack; and
a read station that includes an inlet for receiving a strand from the racetrack, a read head for detecting bases or collections of bases in the strand to read out the binary sequence directly from the strand, and one or more outlets for disposing of the strand.

32. A storage device, comprising:
a patterned substrate having a network of liquid-filled canals; and
strands of molecular material encoded with a sequence of binary data in the liquid-filled canals and movable therein between different locations on the substrate.

33. The storage device of claim 32, further comprising:
a plurality of micro-fluidic valves that control access to the stored strands in addressable locations; and
a transport mechanism that moves the strands around in the liquid-filled canals.

34. The storage device of claim 33,.wherein the strands are electrically charged, said transport mechanism comprising electrodes that establish an electric field gradient in the network of liquid-filled canals that pull the strands through the canals.

35. The storage device of claim 33, wherein the transport mechanism comprises a laser that forms optical tweezers that grab the strands and pull them through the liquid.

36. The storage device of claim 33, wherein the transport mechanism comprises at least one micro-fluidic pump that induces a current in the liquid-filled canals that moves the strands.

37. The storage device of claim 32, further comprising a write station having an inlet for receiving molecular bases, a write head that synthesizes the bases into strands so that a particular sequence of binary data is encoded in a base-sequence of the strand, and an outlet that directs the strand into the network of liquid-filled canals.

38. The storage device of claim 32, further comprising a write station having an inlet for receiving blank,strands of molecular material, a write head that modifies the strand to encode a particular sequence of binary data in a base-sequence of the strand, and an outlet that directs the strand into the network of liquid-filled canals.

39. The storage device of claim 32, wherein the strand comprises a number of bases or collections of bases encoded with the binary data, further comprising a read station that includes an inlet valve for receiving a strand from the liquid-filled canals, a read head for detecting each base or collection of bases to read out the binary sequence directly from the strand, and one or more outlets for disposing of the molecular material.

40. The storage device of claim 33, wherein the micro-fluidic valves, comprise:
an inlet;
first and second outlets;
a switch block; and
an actuator that moves the switch block back-and-forth to alternately block said first and second outlet.

41. A storage device, comprising:
a patterned substrate having a network of liquid-filled canals that define parking lots and a racetrack;
a write station that synthesizes distinct molecular bases in-situ into strands to encode a sequence of binary data in the base-sequence of the strand;
a read station that detects bases or collections of bases to read out the binary data sequence directly from the strand;
a plurality of micro-fluidic valves that control access to the parking lots and read and write stations in response to an external signal; and
a transport mechanism that moves the strands between the parking lots and the read and write stations via the network of liquid-filled canals.

42. A method of fabricating a storage device, comprising:
Patterning a wafer to form ridges and canals that define a plurality of parking lots, a racetrack that interconnects the parking lots and to form chambers that define a read station and a write station;
Processing the wafer using micro-fluidic fabrication technologies to define micro-fluidic valves in the canals that control access to and from the parking lots and the read and write stations;
Filling the canals with liquid;
Fabricating a control wafer to define a plurality of addressing lines;
Mounting the control wafer on the wafer so that the addressing lines control the micro-fluidic valves; and
Storing at least one strand of molecular material encoded with a sequence of binary data in the liquid-filled canal for at least one said parking lot.

43. A method of storing and retrieving a sequence of binary data, comprising:
Writing in-situ a strand of molecular bases that represents a sequence of binary data;
Moving the strand to a memory address;
Storing the strand at the memory address;
Moving the strand from the memory address, to a read location; and
Reading each base or collection of bases in the strand to determine an information unit of binary data.

44. The method of claim 43, wherein the step of writing the strand includes receiving a blank strand and modifying the strand to encode the binary data.

45. The method of claim 43, wherein the step of writing the strand includes receiving distinct molecular bases and synthesizing them into strands to encode the binary data.

46. The method of claim 43, wherein writing step encodes the binary data into the base-sequence of strand.

47. The storage device of claim 43, wherein the writing step uses the strand as a support structure on which to encode the binary data.

48. The method of claims 45 and 46, wherein the strand of molecular bases is written by,
anchoring one end of a seed strand,
applying a voltage to cause a free-floating end of the seed strand to enter through a nano-pore to a selected reservoir where a single molecular base and blocking group are added to the free-floating end of the seed strand;
extracting the strand from the reservoir; and
removing the blocking group from the seed strand to prepare the strand for entry into the next reservoir.

49. The method of claims 45 and 46, wherein the strand is written by,
storing different bases in a buffer solution in at least, two different reservoirs;
extracting a single base through nano-pores in the reservoirs into a first chamber filled with buffer solution and enzymes;
joining the base to grow a strand;
repeating the extraction and joinder until the strand is encoded with the binary sequence of data; and
transferring the strand to a second chamber where it can be moved to the memory address.

50. The method of claim 49, further comprising:
sensing the extraction of a base to close the nano-pores so that only one base is joined to the strand at a time; and
sensing the strand as it passes from the first chamber through a nano-pore to the second chamber to ensure that the strand represents the sequence of binary data.

51. The method of claims 44 and 46, wherein the strand is written by,
receiving a blank strand of bases, each base having at least two possible states; and
selectively transforming the state of each base as the strand is pulled past a write head to write the sequence of binary data into the strand.

52. The method of claim 51, wherein the bases are separated by inert segments in the blank strand, further comprising after all of the bases are transformed,
excising the inert segments from the strand; and
splicing the active molecules back together to reform the strand.

53. The method of claims 44 and 47, wherein the strand of molecules is written by,
chemically modifying the trans side of a chamber wall with surface attached photosensitizer groups capable of reducing a certain nano-particle;
pulling a strand of molecules and the certain nano-particles through an ion-channel formed in a chamber wall; and
emitting laser to excite the photosensitizers and activate reduction of the nano-particles to form nano-clusters bound to the strand at selected locations to encode the sequence of binary data.

54. The method of claims 45 and 46, wherein the strand of molecules is written using a ring-opening metathesis polymerization (ROMP) process.

55. The method of claim 43, wherein the strand is read by applying a voltage across a membrane having a nano-pore formed therein thereby creating an ionic current and pulling strands through the nano-pore thereby creating fluctuations in the ionic current.

56. The method of claim 43, wherein the strand is read by passing it by a microscopic probe that detects the base or collection of bases.

57. The method of claim 43, wherein after the strand is read the strand is destroyed.

58. The method of claim 43, wherein-after the strand is read the strand is broken into its constituent molecules and recycled.

59. The method of claim 43, wherein after the strand is read it is returned to the memory address.

60. The method of claim 43, wherein the strands are moved by,
electrically charging the strands; and
establishing an electric field gradient in the liquid-filled canals that pulls the strands around.

61. The method of claim 43, wherein the strands are moved by forming optical tweezers that grab the strands and pull them around.

62. The method of claim 43, wherein the strands are moved by pumping and thereby inducing a flow current in the liquid-filled canals that move the strands.

63. A method of fabricating a nano-pore in-situ for a read station in a storage device, comprising:
forming first and second chambers having a shared wall;
forming a hole in said shared wall; and
depositing nano-particles in the hole to shrink its size.

64. The method of claim 63, wherein the nano-particles are deposited using an electroless-plating process.

65. The method of claim 63, further comprising measuring an electric current through the shrinking hole and stopping deposition when the current reaches a certain value.
